(19) United States
(12) Patent Application Publication
(10) Pub. No.: US 2007/0183552 A1
(43) Pub. Date: Aug. 9, 2007

(54) Clock and data recovery circuit including first and second stages

(76) Inventors: Anthony Fraser Sanders, Haar (DE); Dirk Scheideler, Munchen (DE); Edoardo Prete, Munchen (DE)

Correspondence Address: DICKE, BILLIG & CZAJA, FIFTH STREET TOWERS, 100 SOUTH FIFTH STREET, SUITE 2200, MINNEAPOLIS, MN, 55402, US

(21) Appl. No.: 11/346,903

(22) Filed: Feb. 3, 2006

(51) Int. Cl. H03D 3/24

(52) U.S. Cl. 375/376

(57) ABSTRACT

A clock and data recovery circuit including a first circuit and a second circuit. The first circuit is configured to receive a clock signal and a phase control signal and to lock onto the clock signal and provide a cleaned clock signal. The second circuit is configured to receive a data signal and the cleaned clock signal and to sample the data signal via the cleaned clock signal and provide the phase control signal. The first circuit adjusts the phase of the cleaned clock signal based on the phase control signal.

### BACKGROUND

Typically, a system includes a number of integrated circuits that communicate with one another to perform system applications. The system can be any suitable system, such as a computer system, a network system, or a control system. Often, the system includes one or more host controllers and one or more electronic subsystem assemblies. To perform system functions, the host controller(s) and subsystem assemblies communicate via communication links, such as serial and parallel communication links.

In a computer system, the one or more subsystem assemblies may include a dual in-line memory module (DIMM), a graphics card, an audio card, a facsimile card, and/or a modem card. Serial communication links include links that implement the fully buffered DIMM (FB-DIMM) advanced memory buffer (AMB) standard, the peripheral component interconnect express (PCIe) standard, or any other suitable serial communication link interface.

An AMB chip is a key device in a FB-DIMM. The AMB has two serial links, one for upstream traffic and the other for downstream traffic, and a bus to on-board memory, such as dynamic random access memory (DRAM) in the FB-DIMM. Serial data from the host controller sent through the downstream serial link (southbound) is temporarily buffered, and then sent to memory in the FB-DIMM. The serial data contains the address, data, and command information given to the memory, converted in the AMB, and sent out to the memory bus. The AMB writes in and reads out from the memory as instructed by the host controller. The read data is converted to serial data, and sent back to the host controller on the upstream serial link (northbound).

The AMB also performs as a repeater between FB-DIMMs on the same channel. The AMB transfers information from a primary southbound link connected to the host controller or an upper AMB to a lower AMB in the next FB-DIMM via a secondary southbound link. The AMB receives information in the lower FB-DIMM from a secondary northbound link, and after merging the information with information of its own, sends it to the upper AMB or host controller via a primary northbound link. This forms a daisy-chain among FB-DIMMs. A key attribute of the FB-DIMM channel architecture is the high-speed, serial, point-to-point connection between the host controller and FB-DIMMs on the channel. The AMB standard is based on serial differential signaling.

PCIe is also a high-speed, serial link that communicates data via differential signal pairs. A PCIe link is built around a bidirectional, serial, point-to-point connection known as a “lane”. At the electrical level, each lane utilizes two unidirectional low voltage differential signaling pairs, a transmit pair and a receive pair, for a total of 4 data wires per lane. A connection between any two PCIe devices is known as a link, and is built up from a collection of 1 or more lanes. All PCIe devices minimally support single-lane (×1) links. Devices may optionally support wider links composed of ×2, ×4, ×8, ×12, ×16, ×32, or more lanes.

Data transmitted in a system can be recovered via a clock and data recovery (CDR) circuit. Typically, a CDR circuit receives a data stream and recovers a clock signal and data from the received data stream. The CDR circuit is capable of tracking jitter up to a relatively low frequency, such as up to 3 Mega-Hertz (MHz) in a 10 Giga-bits per second (Gbps) system. The tracking frequency of the CDR circuit scales with the bit rate of the system.

To enable tracking of higher frequency jitter, a clock signal can be forwarded with the data. The clock signal and data include correlated jitter, i.e. jitter common to both signals, and uncorrelated jitter, i.e. jitter not common to both signals. Due to the correlated jitter, the clock signal can be used by the CDR circuit to track higher frequency jitter, such as jitter up to 100 MHz in a 10 Gbps system. Where, the tracking frequency scales with the bit rate of the system. However, care must be taken that even higher frequency components in the clock signal are not tracked by or influence the CDR circuit.

Sometimes, a phase locked loop (PLL) is included to receive and clean the clock signal. The PLL has a bandwidth just greater than the maximum tracked jitter frequency. The clean up PLL filters and attenuates the higher frequency components of the clock signal to provide a cleaned clock signal. Typically, the CDR circuit includes an adjustable phase generator that provides a sampling clock. The phase generator is sourced by the cleaned clock signal and steered via phase error between the sampling clock and the data stream. However, adding a clean up PLL increases the complexity of the circuit, adds to the physical size of the chip, and increases the power requirements.

For these and other reasons there is a need for the present invention.

### SUMMARY

One aspect of the present invention provides a clock and data recovery circuit including a first circuit and a second circuit. The first circuit is configured to receive a clock signal and a phase control signal and to lock onto the clock signal and provide a cleaned clock signal. The second circuit is configured to receive a data signal and the cleaned clock signal and to sample the data signal via the cleaned clock signal and provide the phase control signal. The first circuit adjusts the phase of the cleaned clock signal based on the phase control signal.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a diagram illustrating one embodiment of a system according to the present invention.

FIG. 2 is a diagram illustrating one embodiment of a CDR circuit.

FIG. 3 is a diagram illustrating one embodiment of a CDR circuit that is similar to the CDR circuit of FIG. 2.

FIG. 4 is a diagram illustrating one embodiment of a clock phase detector.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

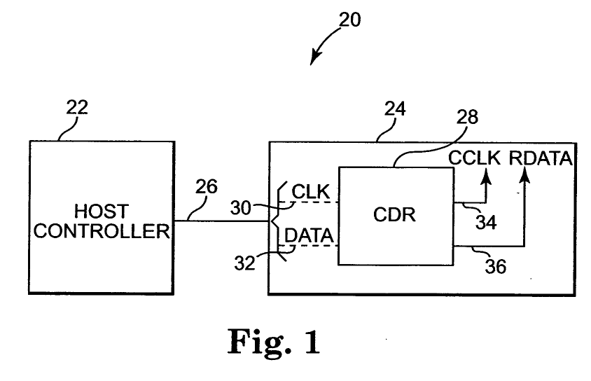

FIG. 1 is a diagram illustrating one embodiment of a system 20 according to the present invention. System 20 can be any suitable system, such as a computer system, a network system, or a control system. System 20 includes a host controller 22 and a subsystem assembly 24. Host controller 22 is electrically coupled to subsystem assembly 24 via communications link 26. Host controller 22 controls subsystem assembly 24 via communications link 26 to provide a system function.

In one embodiment, system 20 is a computer system and host controller 22 is a memory controller. In one embodiment, subsystem assembly 24 is an FB-DIMM and host controller 22 controls the FB-DIMM to provide a system memory function. In other embodiments, subsystem assembly 24 is any suitable subsystem assembly, such as a graphics card, an audio card, a facsimile card, or a modem card, and host controller 22 controls subsystem assembly 24 to provide the corresponding system function.

Subsystem assembly 24 includes at least one CDR circuit 28 that receives a clock signal CLK at 30 and a data signal or data stream DATA at 32 and provides a cleaned clock signal CCLK at 34 and recovered data RDATA at 36. CDR circuit 28 is electrically coupled to host controller 22 via clock communications path 30, data communications path 32, and communications link 26. CDR circuit 28 is electrically coupled to circuitry in subsystem assembly 24 via clock output path 34 and recovered data output path 36. In one embodiment, clock communications path 30 includes one or more buffers that receive signals from host controller 22 via communications link 26 and provide buffered signals to CDR circuit 28. In other embodiments, clock communications path 30 includes any suitable circuitry that receives signals from host controller 22 via communications link 26 and provides signals to CDR circuit 28. In other embodiments, clock communications path 30 does not include any other circuit(s). In one embodiment, data communications path 32 includes one or more buffers that receive signals from host controller 22 via communications link 26 and provide buffered signals to CDR circuit 28. In other embodiments, data communications path 32 includes any suitable circuitry that receives signals from host controller 22 via communications link 26 and provides signals to CDR circuit 28. In other embodiments, data communications path 32 does not include any other circuit(s).

CDR circuit 28 receives clock signal CLK at 30 and locks onto clock signal CLK at 30 to provide cleaned clock signal CCLK at 34. CDR circuit 28 is configured to respond to phase changes, including jitter, in clock signal CLK at 30 that occur at high frequencies to provide cleaned clock signal CCLK at 34. In one embodiment, CDR circuit 28 is configured to respond to phase changes, including jitter, in clock signal CLK at 30 that occur at frequencies up to at least 100 MHz in a 10 Gbps system.

CDR circuit 28 receives data signal DATA at 32 and samples data signal DATA at 32 via cleaned clock signal CCLK at 34 to provide recovered data RDATA at 36. Sampling data signal DATA at 32 via cleaned clock signal CCLK at 34 substantially removes correlated phase changes between clock signal CLK at 30 and data signal DATA at 32, up to the filter frequency, from being a data sampling reliability issue.

The difference between the phase of the data bits in data signal DATA at 32 and the phase of cleaned clock signal CCLK at 34 is used to provide a phase control signal. The phase of cleaned clock signal CCLK at 34 is adjusted based on the phase control signal. This substantially removes uncorrelated phase changes between clock signal CLK at 30 and data signal DATA at 32 up to a filter frequency from being a data sampling reliability issue. In one embodiment, the filter frequency is up to 3 MHz in a 10 Gbps system.

CDR circuit 28 does not need a phase generator to generate a sampling clock. Instead, the sampling clock is cleaned clock signal CCLK at 34. Thus, CDR circuit 28 has a reduced physical size, is less complex, and requires less power, which reduces the cost of the circuit, subsystem assembly, and or system that includes CDR circuit 28.

In one embodiment, communications link 26 includes one or more differential signal pairs that communicate data between host controller 22 and subsystem assembly 24. In one embodiment, communications link 26 includes one differential signal pair. In one embodiment, communications link 26 includes multiple differential signal pairs that communicate data bi-directionally via communications link 26.

In one embodiment, subsystem assembly 24 is an FB-DIMM that is one of multiple FB-DIMMs daisy-chained to host controller 22 via communications link 26. Each of the daisy-chained FB-DIMMs includes an AMB that provides an AMB serial communications link. Each of the FB-DIMMs includes one or more CDR circuits 28 that receive clock and data signals and provide cleaned clock and recovered data signals to the AMB and FB-DIMM subsystem assembly 24.

In one embodiment, host controller 22 and subsystem assembly 24 provide a PCIe serial communications link in communications link 26. Each subsystem assembly 24 includes one or more CDR circuits 28 that receive clock and data signals and provide cleaned clock and recovered data signals to subsystem assembly 24. In other embodiments, host controller 22 and subsystem assembly 24 communicate via any suitable communications link.

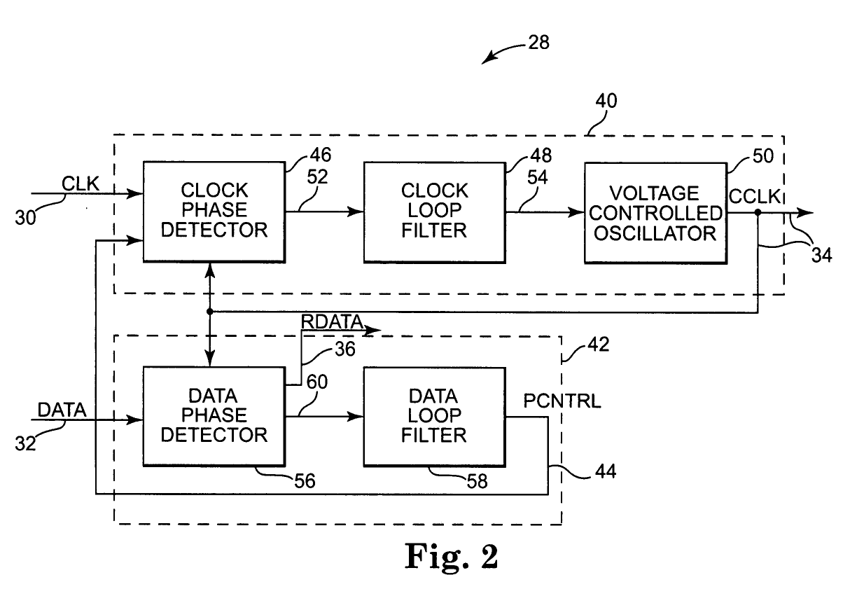

FIG. 2 is a diagram illustrating one embodiment of CDR circuit 28, which receives clock signal CLK via clock communications path 30 and data signal DATA via data communications path 32. CDR circuit 28 provides cleaned clock signal CCLK via clock output path 34 and recovered data RDATA via recovered data output path 36. CDR circuit 28 includes a first circuit 40 and a second circuit 42. First circuit 40 is electrically coupled to second circuit 42 via clock output path 34 and phase control communications path 44. First circuit 40 is electrically coupled to other circuits via clock output path 34 and to circuits, such as host controller 22, via clock communications path 30. Second circuit 42 is electrically coupled to other circuits via recovered data output path 36 and to circuits, such as host controller 22, via data communications path 32.

First circuit 40 is similar to a PLL. First circuit 40 receives clock signal CLK at 30 and provides cleaned clock signal CCLK at 34. First circuit 40 detects phase differences between clock signal CLK at 30 and cleaned clock signal CCLK at 34 and filters the phase difference results. The filtered phase difference results are used to control a voltage controlled oscillator (VCO) that provides cleaned clock signal CCLK at 34. First circuit 40 locks onto clock signal CLK at 30 to provide cleaned clock signal CCLK at 34.

Second circuit 42 receives data signal DATA at 32 and cleaned clock signal CCLK at 34 and provides recovered data RDATA at 36 and a phase control signal PCNTRL at 44. Second circuit 42 samples data signal DATA at 32 via cleaned clock signal CCLK at 34 to provide recovered data RDATA at 36. Data signal DATA at 32 is sampled at the data eye and at data transitions to recover data and determine phase differences between data signal DATA at 32 and cleaned clock signal CCLK at 34. The phase difference results are filtered to provide phase control signal PCNTRL at 44. First circuit 40 receives phase control signal PCNTRL at 44 and adjusts the locking phase of first circuit 40 based on phase control signal PCNTRL at 44. The phase of cleaned clock signal CCLK at 34 is adjusted to lock onto clock signal CLK at 30 and the adjusted cleaned clock signal CCLK at 34 is used to reliably sample data signal DATA at 32.

First circuit 40 includes a clock phase detector 46, a clock loop filter 48, and a VCO 50. Clock phase detector 46 is electrically coupled to clock loop filter 48 via clock phase error communications path 52. Clock loop filter 48 is electrically coupled to VCO 50 via frequency control communications path 54.

Clock phase detector 46 receives clock signal CLK at 30, cleaned clock signal CCLK at 34, and phase control signal PCNTRL at 44. Clock phase detector 46 detects phase differences between clock signal CLK at 30 and cleaned clock signal CCLK at 34. Also, clock phase detector 46 weights the phase differences based on phase control signal PCNTRL at 44 to provide adjusted phase difference results. Clock phase detector 46 provides the adjusted phase difference results via clock phase error communications path 52. In one embodiment, clock phase detector 46 receives multiple phases of cleaned clock signal CCLK at 34. In one embodiment, clock phase detector 46 receives multiple equally spaced phases of cleaned clock signal CCLK at 34.

Clock loop filter 48 receives the adjusted phase difference results via clock phase error communications path 52 and provides a filtered frequency control signal via frequency control communications path 54. Clock loop filter 48 has a high or large bandwidth, which defines the bandwidth of the entire loop and enables first circuit 40 to respond to high frequency phase changes or jitter in clock signal CLK at 30. The high frequency phase changes in clock signal CLK at 30 include correlated jitter between clock signal CLK at 30 and data signal DATA at 32. In one embodiment, clock loop filter 48 is an integrating filter that includes a gain stage. In one embodiment, clock loop filter 48 is dimensioned such that the loop has a bandwidth greater than 100 MHz. In one embodiment, clock loop filter 48 is dimensioned such that the loop has a bandwidth greater than 200 MHz. In other embodiments, clock loop filter 48 is dimensioned such that the loop has any suitable bandwidth.

VCO 50 receives the filtered frequency control signal via frequency control communications path 54 and provides cleaned clock signal CCLK at 34. The frequency control signal controls the oscillation frequency and phase of cleaned clock signal 34. In one embodiment, multiple phases of cleaned clock signal CCLK at 34 are provided to clock phase detector 46 and second circuit 42. In one embodiment, multiple equally spaced phases of cleaned clock signal CCLK at 34 are provided to clock phase detector 46 and second circuit 42.

Second circuit 42 includes data phase detector 56 and data loop filter 58. Data phase detector 56 is electrically coupled to data loop filter 58 via data phase error communications path 60.

Data phase detector 56 receives data signal DATA at 32 and cleaned clock signal CCLK at 34. Data phase detector 56 samples data signal DATA at 32 via cleaned clock signal CCLK at 34 and provides recovered data RDATA at 36. Also, data phase detector 56 provides phase difference results via data phase error communications path 60. In one embodiment, data signal DATA at 32 is sampled at the data eye and at data transitions to recover data and determine the phase differences between data signal DATA at 32 and cleaned clock signal CCLK at 34. In other embodiments, data phase detector 56 is any other suitable type of phase detector.

Data loop filter 58 receives the phase difference results via data phase error communications path 60 and filters the phase difference results to provide phase control signal PCNTRL at 44. In one embodiment, data phase detector 56 receives multiple phases of cleaned clock signal CCLK at 34. In one embodiment, data phase detector 56 receives multiple equally spaced phases of cleaned clock signal CCLK at 34.

First circuit 40 including clock phase detector 46 weights the clock phase differences based on phase control signal PCNTRL at 44 and provides the adjusted phase difference results. First circuit 40 locks onto clock signal CLK at 30 and provides cleaned clock signal CCLK at 34 via the filtered frequency control signal, which includes adjustments based on phase control signal PCNTRL at 44. The cleaned clock signal CCLK at 34 is used to reliably sample data signal DATA at 32.

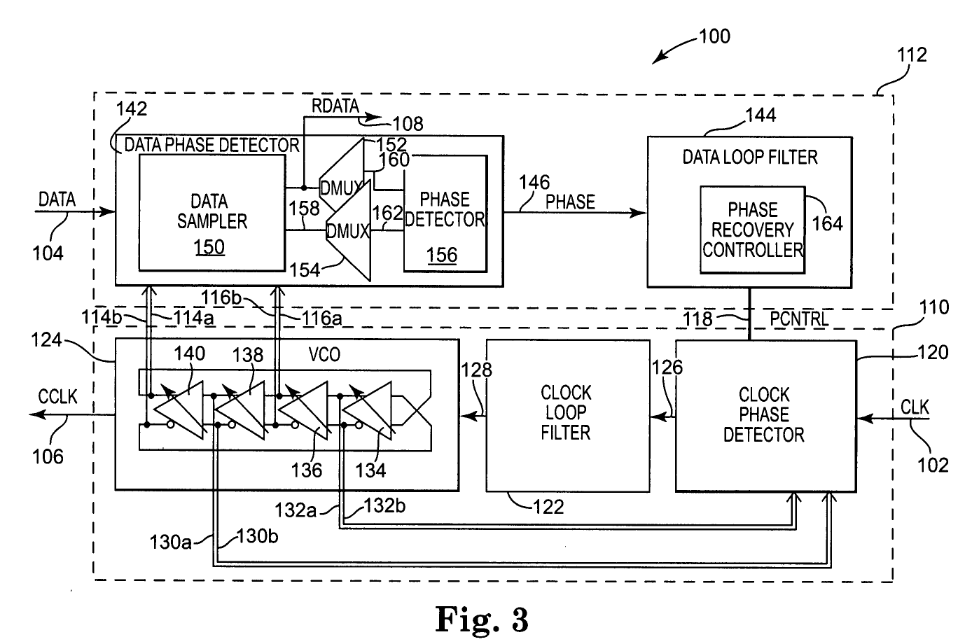

FIG. 3 is a diagram illustrating one embodiment of a CDR circuit 100, which receives clock signal CLK via clock communications path 102 and data signal DATA via data communications path 104. CDR circuit 100 provides cleaned clock signal CCLK via clock output path 106 and recovered data RDATA via recovered data output path 108.

CDR circuit 100 includes a first circuit 110 and a second circuit 112. First circuit 110 is electrically coupled to second circuit 112 via first complementary sampling clock paths 114a and 114b and second complementary sampling clock paths 116a and 116b. Also, first circuit 110 is electrically coupled to second circuit 112 via phase control communications path 118. First circuit 110 is electrically coupled to other circuits via clock output path 106 and to circuits, such as host controller 22, via clock communications path 102. Second circuit 112 is electrically coupled to other circuits via recovered data output path 108 and to circuits, such as host controller 22, via data communications path 104.

First circuit 110 is similar to a PLL. First circuit 110 receives clock signal CLK at 102 and provides cleaned clock signal CCLK at 106. First circuit 110 detects phase differences between clock signal CLK at 102 and multiple phases of cleaned clock signal CCLK at 106. First circuit 110 filters the phase differences and the filtered phase difference results are used to control a VCO that provides cleaned clock signal CCLK at 106. First circuit 110 locks onto clock signal CLK at 102 to provide cleaned clock signal CCLK at 106.

Second circuit 112 receives data signal DATA at 104 and multiple phases of cleaned clock signal CCLK at 106 via first complementary sampling clock paths 114a and 114b and second complementary sampling clock paths 116a and 116b. Second circuit 112 provides recovered data RDATA at 108 and a phase control signal PCNTRL at 118. Second circuit 112 samples data signal DATA at 104 via the multiple phases of cleaned clock signal CCLK at 106 to provide recovered data RDATA at 108. Data signal DATA at 104 is sampled at the data eye and at data transitions or edges to recover the data and determine phase differences between data signal DATA at 104 and cleaned clock signal CCLK at 106. The phase difference results are filtered to provide phase control signal PCNTRL at 118.

First circuit 110 receives phase control signal PCNTRL at 118 and adjusts the locking phase of first circuit 110 based on phase control signal PCNTRL at 118. First circuit 110 weights the phase difference results between clock signal CLK at 102 and multiple phases of cleaned clock signal CCLK at 106 via phase control signal PCNTRL at 118. This shifts or adjusts cleaned clock signal CCLK at 106 and first circuit 110 locks onto clock signal CLK at 102 at a different locking phase. Multiple phases of the adjusted cleaned clock signal CCLK at 106 are used to reliably sample data signal DATA at 104.

First circuit 110 includes a clock phase detector 120, a clock loop filter 122, and a VCO 124. Clock phase detector 120 is electrically coupled to clock loop filter 122 via clock phase error communications path 126 and to second circuit 112 via phase control communications path 118. Clock loop filter 122 is electrically coupled to VCO 124 via frequency control communications path 128. VCO 124 is electrically coupled to clock phase detector 120 via first complementary compare clock paths 130a and 130b and second complementary compare clock paths 132a and 132b. Also, VCO 124 is electrically coupled to second circuit 112 via first complementary sampling clock paths 114a and 114b and second complementary sampling clock paths 116a and 116b.

Clock phase detector 120 receives clock signal CLK at 102, multiple phases of cleaned clock signal CCLK at 106 via first complementary compare clock paths 130a and 130b and second complementary compare clock paths 132a and 132b, and phase control signal PCNTRL via phase control communications path 118. Clock phase detector 120 receives multiple equally spaced phases of cleaned clock signal CCLK at 106 and compares them to clock signal CLK at 102. Clock phase detector 120 detects phase differences between clock signal CLK at 102 and the multiple phases of cleaned clock signal CCLK at 106 and weights the phase differences based on phase control signal PCNTRL at 118 to provide adjusted phase difference results. Clock phase detector 120 provides the adjusted phase difference results via clock phase error communications path 126.

In one embodiment, clock phase detector 120 includes multiple phase detector circuits. Each of the multiple phase detector circuits compares the phase of clock signal CLK at 102 to one or more of the equally spaced phases of cleaned clock signal CCLK at 106. Each of the phase detectors is coupled to a current source that provides current based on the detected phase differences. The currents are regulated or weighted via phase control signal PCNTRL at 118 that includes multiple bit lines for weighting the phase differences. The weighted currents are summed to provide phase difference results via clock phase error communications path 126. Thus, phase control signal PCNTRL at 118 controls and adjusts the weighting of the phase detectors and the multiple phases of cleaned clock signal CCLK at 106.

Clock loop filter 122 receives the adjusted phase difference results via clock phase error communications path 126 and provides a filtered frequency control signal via frequency control communications path 128. Clock loop filter 122 has a high or large bandwidth and first circuit 110 responds to high frequency phase changes or jitter in clock signal CLK at 102. The high frequency phase changes in clock signal CLK at 102 include correlated jitter between clock signal CLK at 102 and data signal DATA at 104. In one embodiment, clock loop filter 122 is an integrating filter that includes a gain stage. In one embodiment, clock loop filter 122 has a bandwidth greater than 100 MHz. In one embodiment, clock loop filter 122 has a bandwidth greater than 200 MHz. In other embodiments, clock loop filter 122 has any suitable bandwidth.

VCO 124 includes four stages 134, 136, 138, and 140. Complementary outputs of fourth stage 140 are cross coupled to the inputs of first stage 134 via first complementary sampling clock paths 114a and 114b. Complementary outputs of first stage 134 are provided as inputs to second stage 136 via second complementary compare clock paths 132a and 132b. Complementary outputs of second stage 136 are provided as inputs to third stage 138 via second complementary sampling clock paths 116a and 116b. Complementary outputs of third stage 138 are provided as inputs to fourth stage 140 via first complementary compare clock paths 130a and 130b. Cleaned clock signal 106 is taken from between any two of the four stages 134, 136, 138, and 140.

VCO 124 provides four equally spaced phases of cleaned clock signal CCLK at 106 to second circuit 112 via first complementary sampling clock paths 114a and 114b and second complementary sampling clock paths 116a and 116b. Also, VCO 124 provides another four equally spaced phases of cleaned clock signal CCLK at 106 to clock phase detector 120 via first complementary compare clock paths 130a and 130b and second complementary compare clock paths 132a and 132b. The clock rate of clock signal CLK at 102 is at a ratio of one half the bit rate of data signal DATA at 104. For example, in one embodiment, the bit rate of data signal DATA at 104 is 10 Gbps and the clock rate of clock signal CLK at 102 is 5 Giga-Hertz (GHz). In one embodiment, the clock rate of clock signal CLK at 102 is at a ratio of greater than one half the bit rate of data signal DATA at 104, such as at the full data bit rate. In one embodiment, the clock rate of clock signal CLK at 102 is at a ratio of less than one half the bit rate of data signal DATA at 104, such as at one quarter or one eighth the bit rate. In other embodiments, the clock rate of clock signal CLK at 102 can be at any suitable ratio to the bit rate of data signal DATA at 104. Also, in other embodiments, VCO 124 can include any suitable number of stages and provide any suitable number of phases. In one embodiment, VCO 124 is an interpolating VCO. In other embodiments, VCO 124 is any suitable type of VCO.

VCO 124 receives the filtered frequency control signal via frequency control communications path 128 and provides cleaned clock signal CCLK at 106. The frequency control signal controls the oscillation frequency of cleaned clock signal CCLK at 106 and adjusts the phase of cleaned clock signal CCLK at 106.

Second circuit 112 includes data phase detector 142 and data loop filter 144. Data phase detector 142 is electrically coupled to data loop filter 144 via data phase error communications path 146.

Data phase detector 142 receives data signal DATA at 104 and multiple phases of cleaned clock signal CCLK at 106 via first complementary sampling clock paths 114a and 114b and second complementary sampling clock paths 116a and 116b. Data phase detector 142 samples data signal DATA at 104 via the multiple phases of cleaned clock signal CCLK at 106 and provides recovered data RDATA at 108. Data signal DATA at 104 is sampled at the data eye and at data transitions or edges to recover data and determine phase differences between data signal DATA at 104 and the multiple phases of cleaned clock signal CCLK at 106. Data phase detector 142 provides the phase difference results via data phase error communications path 146.

Data phase detector 142 includes data sampler 150, data eye de-multiplexer 152, data edge de-multiplexer 154, and phase detector 156. Data sampler 150 is electrically coupled to data eye de-multiplexer 152 via data eye communications path 108 and to data edge de-multiplexer 154 via data edge communications path 158. The output of data eye de-multiplexer 152 is electrically coupled to phase detector 156 via data de-multiplexer communications path 160 and the output of data edge de-multiplexer 154 is electrically coupled to phase detector 156 via edge de-multiplexer communications path 162.

Data sampler 150 receives data signal DATA at 104 and multiple phases of cleaned clock signal CCLK at 106. Data sampler 150 samples data signal DATA at 104 via the multiple phases of cleaned clock signal CCLK at 106 and provides recovered data RDATA at 108 and edge data at 158. Data eye de-multiplexer 152 receives recovered data RDATA at 108 and de-serializes the data to lower frequency data for phase detector 156. Data edge de-multiplexer 154 receives edge data and de-serializes the data to lower frequency data for phase detector 156. Phase detector 156 includes phase detectors, such as exclusive OR circuits, to detect phase differences. Data phase detector 142 provides phase difference results PHASE at 146 via data phase error communications path 146. In one embodiment, phase difference results PHASE at 146 include two signals, an early signal and a late signal.

Data loop filter 144 includes phase recovery controller 164, which receives phase difference results PHASE via data phase error communications path 146. Data loop filter 144 filters the received phase difference results PHASE and phase recovery controller 164 provides phase control signal PCNTRL at 118. In one embodiment, phase recovery controller 164 provides multiple bit lines of data in phase control signal PCNTRL at 118. In one embodiment, phase recovery controller 164 provides 64 bit lines of data in phase control signal PCNTRL at 118.

Clock phase detector 120 detects phase differences between clock signal CLK at 102 and the multiple phases of cleaned clock signal CCLK at 106 and weights the phase differences based on phase control signal PCNTRL at 118 to provide adjusted phase difference results. Clock phase detector 120 provides the adjusted phase difference results via clock phase error communications path 126. First circuit 110 locks onto clock signal CLK at 102 and provides cleaned clock signal CCLK at 106 via the filtered frequency control signal, which includes adjustments based on phase control signal PCNTRL at 118. The cleaned clock signal CCLK at 106 is used to reliably sample data signal DATA at 104.

CDR circuit 28 of FIG. 2 and CDR circuit 100 do not need a phase generator to generate a sampling clock. Instead, the sampling clock is the cleaned clock signal CCLK. Thus, CDR circuit 28 and CDR circuit 100 are less complex circuits that have reduced physical sizes and require less power, which reduces the cost of the circuit, subsystem assembly, and or system that includes the CDR circuit.

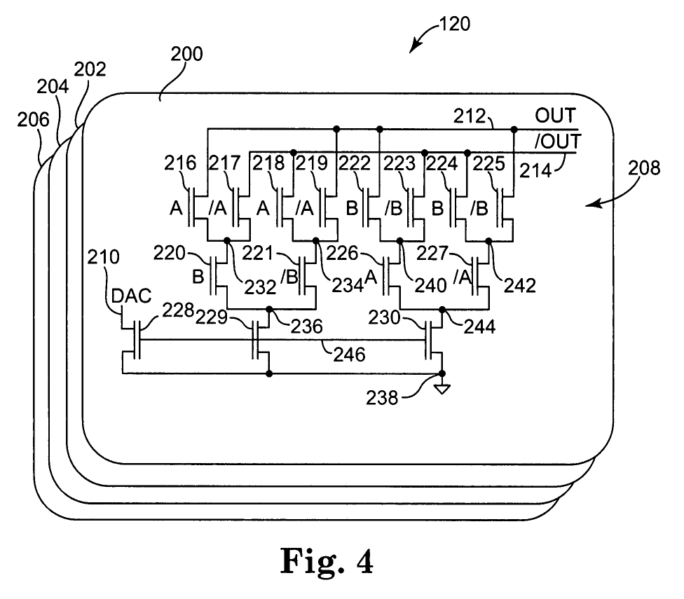

FIG. 4 is a diagram illustrating one embodiment of clock phase detector 120 that includes four phase detector circuits 200, 202, 204, and 206. Each of the four phase detector circuits 200, 202, 204, and 206 is similar to the other three phase detector circuits 200, 202, 204, and 206. The outputs of the four phase detector circuits 200, 202, 204, and 206 are electrically coupled in parallel to provide summed phase difference results to clock loop filter 122.

In one embodiment, each of the four phase detectors 200, 202, 204, and 206 receives adjacent phases of cleaned clock signal CCLK at 106 from VCO 124. Phase detector circuit 200 receives phases 0 and 90, phase detector circuit 202 receives phases 90 and 180, phase detector circuit 204 receives phases 180 and 270, and phase detector circuit 206 receives phases 270 and 0. Each of the received phases is compared to clock signal CLK at 102 via a balanced exclusive OR circuit (XOR) to provide phase difference results.

Clock phase detector 120 includes a digital to analog converter circuit (not shown) that receives phase control signal PCNTRL at 118. The digital to analog converter circuit provides one or more digital to analog converter signals, such as digital to analog converter signal DAC at 210, to each of the four phase detector circuits 200, 202, 204, and 206. The digital to analog converter signals are used to weight the phase difference results from each of the four phase detector circuits 200, 202, 204, and 206.

Phase detector circuit 200 includes balanced XOR 208 that receives digital to analog converter signal DAC at 210 for weighting output signals OUT at 212 and /OUT at 214. Output signal OUT at 212 is the complement of output signal /OUT at 214. Phase detector circuit 200 and XOR 208 receive a first complementary pair of input signals A and /A and a second complementary pair of input signals B and /B, which are compared to provide phase difference results. One of the first and second complementary pairs of input signals is one phase of cleaned clock signal CCLK at 106 and the other one of the first and second complementary pairs of input signals is clock signal CLK at 102.

XOR 208 includes a first set and a second set of n-channel metal oxide semiconductor (NMOS) transistors. The first set of NMOS transistors includes transistors 216-221 and the second set of NMOS transistors includes transistors 222-227. XOR 208 also includes current source transistors 228, 229, and 230. The gates of transistors 216, 218, and 226 receive input signal A. The gates of transistors 217, 219, and 227 receive input signal /A. The gates of transistors 220, 222, and 224 receive input signal B. The gates of transistors 221, 223, and 225 receive input signal /B.

In the first set of NMOS transistors, one side of the drain-source paths of transistors 216 and 219 are electrically coupled at 212 and one side of the drain-source paths of transistors 217 and 218 are electrically coupled at 214. The other side of the drain-source paths of transistors 216 and 217 are electrically coupled at 232 to one side of the drain-source path of transistor 220 and the other side of the drain-source paths of transistors 218 and 219 are electrically coupled at 234 to one side of the drain-source path of transistor 221. The other side of the drain-source paths of transistors 220 and 221 are electrically coupled at 236 to one side of the drain-source path of transistor 229. The other side of the drain-source path of transistor 229 is electrically coupled to a reference at 238, such as ground.

In the second set of NMOS transistors, one side of the drain-source paths of transistors 222 and 225 are electrically coupled at 212 and one side of the drain-source paths of transistors 223 and 224 are electrically coupled at 214. The other side of the drain-source paths of transistors 222 and 223 are electrically coupled at 240 to one side of the drain-source path of transistor 226 and the other side of the drain-source paths of transistors 224 and 225 are electrically coupled at 242 to one side of the drain-source path of transistor 227. The other side of the drain-source paths of transistors 226 and 227 are electrically coupled at 244 to one side of the drain-source path of transistor 230. The other side of the drain-source path of transistor 230 is electrically coupled to the reference at 238.

One side of the drain-source path of transistor 228 receives the digital to analog converter signal DAC at 210. The gates of current source transistors 228, 229, and 230 are electrically coupled at 246. The other side of the drain-source path of transistor 228 is electrically coupled to the reference at 238.

XOR 208 performs an XOR function on the first complementary pair of input signals A and /A and the second complementary pair of input signals B and /B. If input signals A and B are low and input signals /A and /B are high, output signal OUT at 212 is low and output signal /OUT at 214 is high. If input signals A and B are high and input signals /A and /B are low, output signal OUT at 212 is low and output signal /OUT at 214 is high. If input signals A and /B are low and input signals /A and B are high, output signal OUT at 212 is high and output signal /OUT at 214 is low. If input signals /A and B are low and input signals A and /B are high, output signal OUT at 212 is high and output signal /OUT at 214 is low.

The strength or weight of the output signals OUT at 212 and /OUT at 214 is based on the magnitude of the current in digital to analog converter signal DAC at 210, and thus, the magnitude of the current through transistors 229 and 230. The digital to analog converter signal DAC at 210 is controlled via phase control signal PCNTRL at 118 to weight the phase difference results. The outputs of the four phase detector circuits 200, 202, 204, and 206 are electrically coupled in parallel to provide summed phase difference results to clock loop filter 122. In other embodiments, other suitable technologies can be used to design clock phase detector 120.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A clock and data recovery circuit comprising:
a first circuit configured to receive a clock signal and a phase control signal and to lock onto the clock signal and provide a cleaned clock signal; and
a second circuit configured to receive a data signal and the cleaned clock signal and to sample the data signal via the cleaned clock signal and provide the phase control signal, wherein the first circuit adjusts the phase of the cleaned clock signal based on the phase control signal.

2. The clock and data recovery circuit of claim 1, wherein the first circuit comprises a mixer configured to detect multiple phase differences between the clock signal and the cleaned clock signal and to provide multiple outputs that correspond to the multiple phase differences and sum the multiple outputs to obtain a phase error signal.

3. The clock and data recovery circuit of claim 2, wherein the mixer is configured to receive the phase control signal and weight each of the multiple outputs based on the phase control signal to vary the locking phase of the first circuit.

4. The clock and data recovery circuit of claim 2, wherein the first circuit comprises:
a filter configured to receive the phase error signal and provide a frequency control signal; and
a voltage controlled oscillator configured to receive the frequency control signal and to adjust the frequency of the cleaned clock signal based on the frequency control signal to adjust the phase of the cleaned clock signal.

5. The clock and data recovery circuit of claim 1, wherein the first circuit is configured to respond to phase changes in the clock signal that occur at a frequency of up to at least 100 MHz to provide the cleaned clock signal.

6. The clock and data recovery circuit of claim 1, wherein the data signal and the clock signal include uncorrelated phase changes and the second circuit is configured to respond to the uncorrelated phase changes that occur at a frequency of less than 3 MHz to provide the phase control signal.

7. The clock and data recovery circuit of claim 1, wherein the clock rate of the clock signal is at a ratio of one half the bit rate of the data signal.

8. The clock and data recovery circuit of claim 1, wherein the clock rate of the clock signal is at a ratio of greater than one half the bit rate of the data signal.

9. The clock and data recovery circuit of claim 1, wherein the clock rate of the clock signal is at a ratio of less than one half the bit rate of the data signal.

10. A system comprising:
a clock and data recovery circuit configured to receive a clock signal and a data signal and provide a cleaned clock signal and recovered data, wherein the clock signal and the data signal include correlated phase changes and the clock and data recovery circuit comprises:
a first circuit configured to receive the clock signal and a phase control signal and to lock onto the clock signal and provide the cleaned clock signal; and
a second circuit configured to receive the data signal and the cleaned clock signal and to sample the data signal via the cleaned clock signal and provide the phase control signal, wherein the first circuit is configured to adjust the phase of the cleaned clock signal based on the correlated phase changes and the phase control signal.

11. The system of claim 10, wherein the data signal and the clock signal include uncorrelated phase changes and the second circuit is configured to respond to the uncorrelated phase changes to provide the phase control signal.

12. The system of claim 11, wherein the second circuit is configured to respond to the uncorrelated phase changes that occur at a frequency of less than 3 MHz.

13. The system of claim 10, wherein the first circuit comprises a mixer configured to detect multiple phase differences between the clock signal and the cleaned clock signal and to provide multiple outputs that correspond to the multiple phase differences and sum the multiple outputs to obtain a phase error signal.

14. The system of claim 13, wherein the mixer is configured to receive the phase control signal and weight each of the multiple outputs based on the phase control signal to vary the locking phase of the first circuit.

15. The system of claim 10, comprising an advanced memory buffer circuit that includes the clock and data recovery circuit.

16. The system of claim 10, comprising a fully buffered dual in-line memory module that includes the clock and data recovery circuit.

17. A clock and data recovery circuit comprising:
means for locking onto a clock signal to provide a cleaned clock signal;
means for sampling a data signal via the cleaned clock signal;
means for providing a phase control signal; and
means for adjusting the phase of the cleaned clock signal based on the phase control signal.

18. The clock and data recovery circuit of claim 17, wherein the means for adjusting the phase comprises:
means for detecting multiple phase differences between the clock signal and the cleaned clock signal;
means for providing multiple outputs that correspond to the multiple phase differences; and
means for summing the multiple outputs to obtain a phase error signal.

19. The clock and data recovery circuit of claim 18, wherein the means for adjusting the phase comprises:
means for weighting each of the multiple outputs based on the phase control signal.

20. The clock and data recovery circuit of claim 18, wherein the means for locking onto a clock signal comprises:
means for providing a frequency control signal based on the phase error signal; and
means for adjusting the frequency of the cleaned clock signal based on the frequency control signal to adjust the phase of the cleaned clock signal.

21. The clock and data recovery circuit of claim 17, wherein the means for locking onto a clock signal comprises:
means for responding to phase changes in the clock signal that occur at a frequency of up to at least 100 MHz to provide the cleaned clock signal.

22. A method for recovering clock and data signals comprising:
locking onto a clock signal to provide a cleaned clock signal;
sampling a data signal using the cleaned clock signal;
providing a phase control signal; and
adjusting the phase of the cleaned clock signal based on the phase control signal.

23. The method of claim 22, wherein adjusting the phase comprises:
detecting multiple phase differences between the clock signal and the cleaned clock signal;
providing multiple outputs that correspond to the multiple phase differences; and
summing the multiple outputs to obtain a phase error signal.

24. The method of claim 23, wherein adjusting the phase comprises:
weighting each of the multiple outputs based on the phase control signal.

25. The method of claim 23, wherein locking onto a clock signal comprises:
providing a frequency control signal based on the phase error signal; and
adjusting the frequency of the cleaned clock signal based on the frequency control signal to adjust the phase of the cleaned clock signal.

26. The method of claim 22, wherein locking onto a clock signal comprises:
responding to phase changes in the clock signal that occur at a frequency of up to at least 100 MHz to provide the cleaned clock signal.

27. A method for recovering clock and data signals comprising:
receiving a clock signal and a data signal that include correlated phase changes;
locking onto the clock signal to provide a cleaned clock signal;
adjusting the phase of the cleaned clock signal based on the correlated phase changes that occur at a frequency of up to at least 100 MHz;
sampling the data signal via the cleaned clock signal;
providing a phase control signal; and
adjusting the phase of the cleaned clock signal based on the phase control signal.

28. The method of claim 27, wherein:
receiving a clock signal and a data signal comprises receiving uncorrelated phase changes in the clock signal and the data signal; and
providing a phase control signal comprises responding to the uncorrelated phase changes to provide the phase control signal.

29. The method of claim 27, wherein adjusting the phase of the cleaned clock signal based on the phase control signal comprises:
detecting multiple phase differences between the clock signal and the cleaned clock signal;
providing multiple outputs that correspond to the multiple phase differences; and
summing the multiple outputs to obtain a phase error signal.

30. The method of claim 29, wherein adjusting the phase of the cleaned clock signal based on the phase control signal comprises:
weighting each of the multiple outputs based on the phase control signal.
